(19) United States
(12) Patent Application Publication
(10) Pub. No.: US 2023/0057384 A1
(43) Pub. Date: Feb. 23, 2023

(54) HYBRID CARRIER FOR ELECTRONIC SUBSTRATE TECHNOLOGIES

(71) Applicant: Intel Corporation, Santa Clara, CA (US)

(72) Inventors: Jeremy D. ECTON, Gilbert, AZ (US); Brandon C. MARIN, Gilbert, AZ (US); Hiroki TANAKA, Gilbert, AZ (US); Jason M. GAMBA, Gilbert, AZ (US); Srinivas V. PIETAMBARAM, Chandler, AZ (US)

(21) Appl. No.: 17/408,157

(22) Filed: Aug. 20, 2021

(51) Int. Cl. H01L 21/683; H01L 21/48; H01L 23/00; H01L 23/498

(52) U.S. Cl. CPC H01L 21/6835; H01L 21/4857; H01L 23/49816; H01L 23/49822; H01L 23/49838; H01L 24/16; H01L 24/81; H01L 2221/68331; H01L 2221/68345; H01L 2224/16227

(57) ABSTRACT

Embodiments disclosed herein include carriers and methods of using the carriers to assemble electronic packages. In an embodiment, a carrier for electronic packaging assembly comprises a mold layer with a first surface and a second surface. In an embodiment, a plurality of glass substrates are embedded in the mold layer. In an embodiment, individual ones of the glass substrates comprise a third surface and a fourth surface, where the third surface of the glass substrate is substantially coplanar with the first surface of the mold layer.

### TECHNICAL FIELD

Embodiments of the present disclosure relate to electronic packages, and more particularly to package substrates fabricated with a carrier comprising of multiple materials (i.e., hybrid carrier) including but not limited to glass, mold, dielectric, epoxy, and the like.

### BACKGROUND

Despite the many apparent technical advantages of using glass as a carrier material or an integrated part of the package, enabling high yielding processing at the panel scale using existing high density substrate equipment carries many challenges. One such problem is that the clamps and frames common to substrate manufacturing equipment using copper clad laminate (CCL) panels is inherently incompatible with a brittle ceramic like glass. Another is that panel scale carries significant cost benefits, but may require converting to sub-panel scale in order to perform some process steps, including micro ball attach or assembly, among others. The cutting required to enable these processes poses significant limitations on the type of temporary bond film used to detach the devices at the end of the process.

### BRIEF DESCRIPTION OF THE DRAWINGS

FIG. 1A is a plan view illustration of a carrier with a plurality of quarter panel glass substrates embedded in a mold layer, in accordance with an embodiment.

FIG. 1B is a plan view illustration of a carrier with a plurality of glass panels embedded in a mold layer, in accordance with an embodiment.

FIG. 2A is a cross-sectional illustration of a carrier with glass substrates embedded in a mold layer, where two surfaces of each glass substrate are exposed, in accordance with an embodiment.

FIG. 2B is a cross-sectional illustration of a carrier with glass substrates embedded in a mold layer, where a single surface of each glass substrate is exposed, in accordance with an embodiment.

FIG. 2C is a cross-sectional illustration of a carrier with a glass base substrate and a plurality of glass substrates embedded in a mold layer, in accordance with an embodiment.

FIGS. 3A-3J are cross-sectional illustrations depicting a process for assembling electronic packages using a carrier with a plurality of glass substrates embedded in a mold layer, in accordance with an embodiment.

FIGS. 4A-4I are cross-sectional illustrations depicting a process for assembling electronic packages using a carrier with a plurality of glass substrates embedded in a mold layer with a bottom surface of the glass substrates covered by the mold layer, in accordance with an embodiment.

FIGS. 5A-5H are cross-sectional illustrations depicting a process for assembling electronic packages using a carrier with a base die and a plurality of glass substrates embedded in a mold layer, in accordance with an embodiment.

FIG. 6A is a cross-sectional illustration of a plurality of electronic packages over a carrier with a release trench drilled through the package layers, in accordance with an embodiment.

FIG. 6B is a cross-sectional illustration of an electronic package with sloped sidewall profiles created by the release trench, in accordance with an embodiment.

FIG. 7 is a cross-sectional illustration of an electronic system with an electronic package with sloped sidewall profiles, in accordance with an embodiment.

FIG. 8 is a schematic of a computing device built in accordance with an embodiment.

### EMBODIMENTS OF THE PRESENT DISCLOSURE

Described herein are package substrates fabricated with a hybrid glass based carrier, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, existing glass panel carriers have limitations in high volume manufacturing (HVM) environments. One issue is relatively low yielding processes using glass carriers. This is because the majority of handling occurs along the edge of the panel where glass is weakest and most prone to cracks/breaks. As a result, full panel glass processing line yield is relatively low compared to standard organic based carriers/panels. Additional limitations include limitations in terms of thickness and material type.

With regards to scribing for converting from full panel form factors to quarter-panel form factors, conventional scribing approaches put a limitation on glass materials. For example, there is no clear capability to scribe ionized glass. With regards to thickness, following conventional approaches requires thick glass for all stages of the process in order to enable a high yielding glass process utilizing existing substrate infrastructure. While this may not be a major issue for devices built on a glass carrier, applications for those devices requiring integrated glass likely cannot tolerate the large z-height.

There are also issues with quarter panel materials and form factor limitations. For example, a wet saw cutting tool is typically used for the singulation to the quarter panel form factor. However, bond films that can withstand exposure to water without compromising adhesion of the device are uncommon and require extensive engineering and development time.

In yet another issue, panel identification schemes are costly. For example, industry standard marking of glass wafers/panels is to use a T7/M12 mark, which is a SEMI standard mark that requires specialty sensors to read. Converting existing organic panel processing lines to accommodate such markings comes at a significant cost.

Accordingly, embodiments disclosed herein include the use of a carrier with glass substrates that are embedded in a mold layer. Such a hybrid architecture allows for organic materials (e.g., dielectric, prepreg, mold materials, epoxy, etc.) to be incorporated at locations consistent with tool contact/handling points while incorporating glass at locations consistent with the active area (i.e., the patterning area) of the panel to take advantage of flatness (i.e., low total thickness variation (TTV)) and low CTE of glass.

Additionally, such hybrid architectures allow for flexibility in terms of glass materials and thicknesses of the carriers during both full panel and quarter panel processing/assembly. For example, ionized glass can be used for the proposed process flows for improved yield and warpage control. Ionized glass is able to be used since the singulation processes do not need to pass through the glass. Regarding flexibility in the thickness, ultra-thin quarter panel substrates can be included on the carrier, and subsequently integrated into the electronic package as an integrated glass stiffener. The proposed hybrid approach also enables flexibility to optimize cost. For example, a low cost glass can be used for the primary carrier, and a high cost glass (which can also be a functional part of the package) can be used for the active area or quarter panel form factor.

The hybrid carrier approach also allows for a simple method for converting from full panel glass form factor to the quarter panel form factor. That is, there is no need for scribing or cutting through the glass, as the scribe lines may be provided through the mold material. Additionally, a simple method is able to form panel notches necessary for panel identification without requiring new tools and/or tool upgrades.

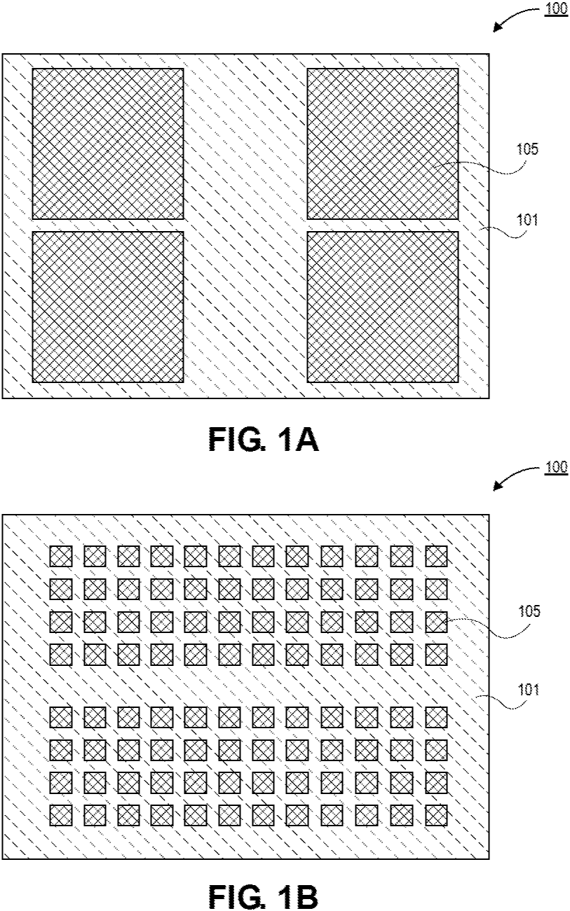

Referring now to FIG. 1A, a plan view illustration of a hybrid carrier 100 is shown, in accordance with an embodiment. In an embodiment, the carrier 100 may be referred to as a hybrid carrier 100 since the carrier 100 comprises both glass substrates 105 and a mold layer 101. For example, a plurality of glass substrates 105 are arranged in the mold layer 101. In the particular embodiment shown in FIG. 1A, four glass substrates 105 are shown. The individual glass substrates 105 may be quarter panel sized, and the mold layer 101 may be panel sized. However, it is to be appreciated that other form factors for the mold layer 101 and the glass substrates 105 may be used.

In an embodiment, the mold layer 101 may be an organic compound. For example, the mold layer 101 may comprise a dielectric material, a prepreg material, mold materials, epoxy, or the like. The glass substrates 105 may be any glass formulation. In a particular embodiment, the glass substrates 105 may comprise an ionized glass formulation. The mold layer 101 may be more mechanically robust than the glass substrates 105. The mold layer 101 may be at locations of the carrier 100 that are contacted by handling equipment (e.g., clamps, frames, etc.). For example, the mold layer 101 may be provided at an outer edge of the carrier 100. Additionally, the mold layer 101 may be provided between edges of the glass substrates 105. As such, simple singulation processes may be provided, since there is no need to cut through the glass substrates 105.

Referring now to FIG. 1B, a plan view illustration of a carrier 100 is shown, in accordance with another embodiment. In the illustrated embodiment, the form factor of the glass substrates 105 is reduced compared to the embodiment shown in FIG. 1A. Instead of being quarter panel sized, the glass substrates 105 may be device sized. That is, each glass substrate 105 may support a single electronic package. While quarter panel form factors and device size form factors are shown for the glass substrates 105, it is to be appreciated that any form factor may be used for the glass substrates 105. Similarly, while the mold layer 101 is shown with a panel form factor, it is to be appreciated that the mold layer 101 may have any form factor as well.

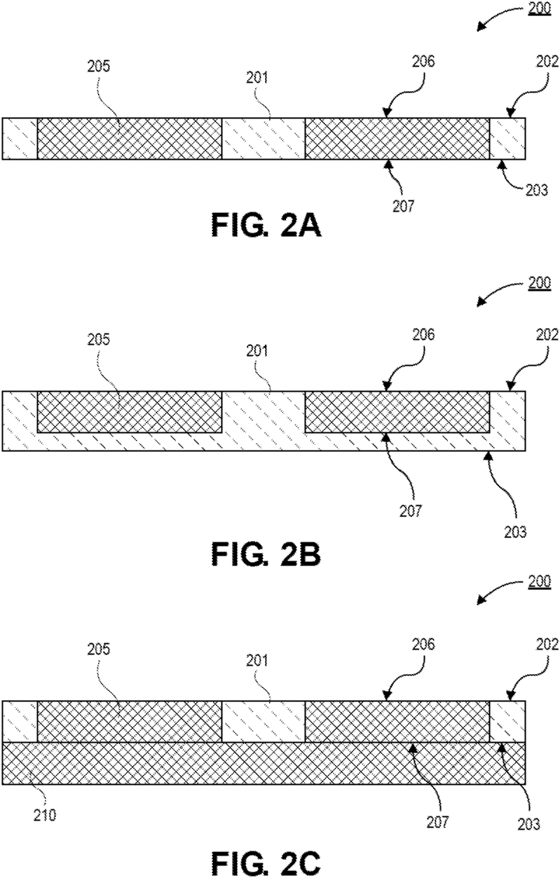

Referring now to FIGS. 2A-2C, cross-sectional illustrations of hybrid carriers are shown, in accordance with various embodiments. The cross-sections shown in FIGS. 2A-2C may be hybrid carriers 200 that are substantially similar to the hybrid carriers 100 shown in the plan view illustrations of FIGS. 1A and 1B.

Referring now to FIG. 2A, a cross-sectional illustration of a carrier 200 is shown, in accordance with an embodiment. In an embodiment, the glass substrates 205 may be embedded in a mold layer 201. The glass substrates 205 may be embedded in the mold layer 201 so that a top surface 206 and a bottom surface 207 of the glass substrates 205 are exposed. For example, top surface 206 of the glass substrate 205 may be substantially coplanar with a top surface 202 of the mold layer 201, and bottom surface 207 of the glass substrate 205 may be substantially coplanar with a bottom surface 203 of the mold layer 201. As used herein, “substantially coplanar” may refer to two surfaces that are within approximately 5 µm of being coplanar with each other.

Referring now to FIG. 2B, a cross-sectional illustration of a carrier 200 is shown, in accordance with an additional embodiment. In an embodiment, the glass substrates 205 may be embedded in the mold layer 201. As opposed to the embodiment shown in FIG. 2A, only a single surface of the glass substrates (i.e., the top surface 206) is exposed. The bottom surface 207 is covered by the mold layer 201.

Referring now to FIG. 2C, a cross-sectional illustration of a carrier 200 is shown, in accordance with yet another embodiment. In an embodiment, the carrier 200 is similar to the carrier 200 in FIG. 2A, with the exception of a base substrate 210 provided below the mold layer 201 and the glass substrates 205. The base substrate 210 may be a glass substrate. While shown as directly contacting the base substrate 210, it is to be appreciated that an adhesive or the like may separate the bottom surface 207 of the glass substrate 205 and the bottom surface 203 of the mold layer 201 from the base substrate 210. While the bottom surface of the carrier 200 (i.e., the bottom of the base substrate 210) may be glass, mechanical robustness is provided on the top surface of the carrier 200 by the mold layer 201.

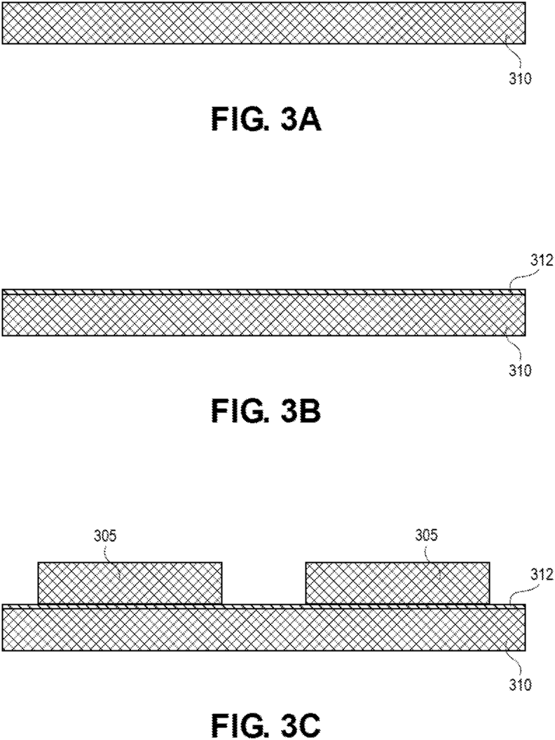

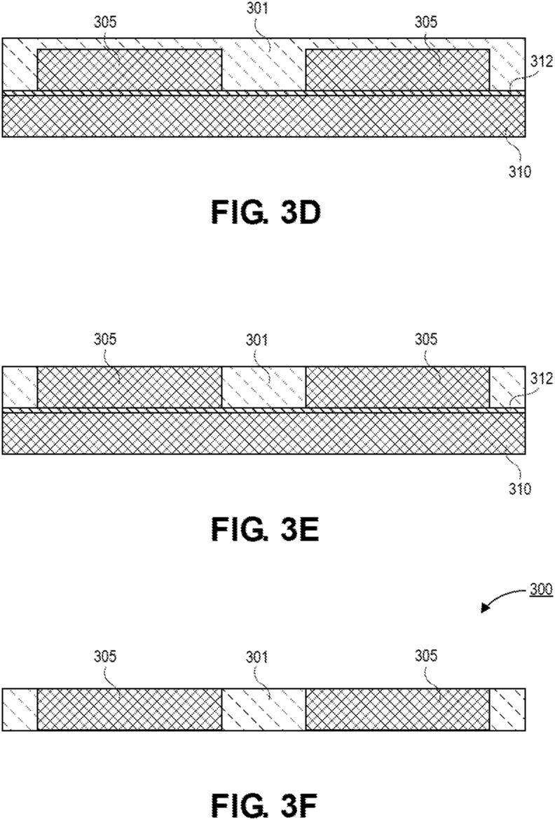

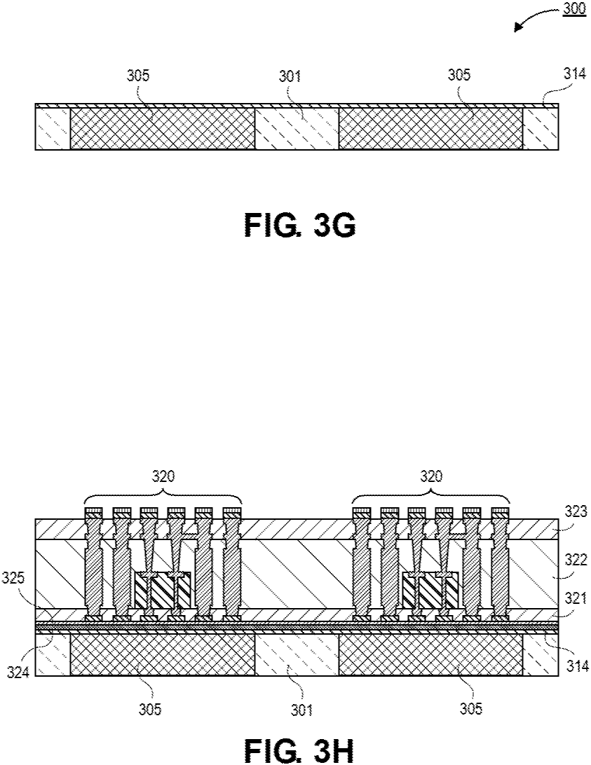

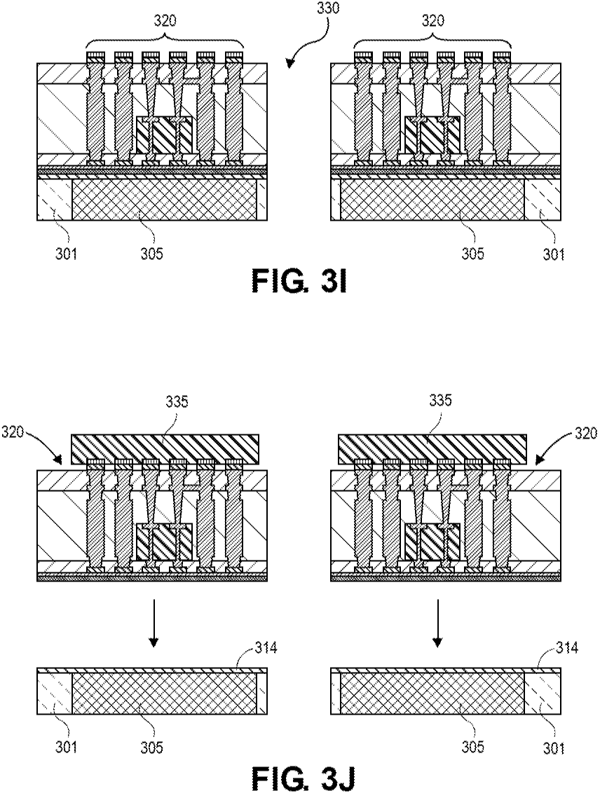

Referring now to FIGS. 3A-3J, a series of cross-sectional illustrations depicting a process for forming a package substrate using a hybrid carrier is shown, in accordance with an embodiment. In an embodiment, the hybrid carrier in FIGS. 3A-3J may be substantially similar to the hybrid carrier 200 in FIG. 2A.

Referring now to FIG. 3A, a cross-sectional illustration of a base substrate 310 is shown, in accordance with an embodiment. In an embodiment, the base substrate 310 may be a full panel sized substrate. Though, it is to be appreciated that other form factors may also be used in other embodiments. In an embodiment, the base substrate 310 may comprise a glass substrate.

Referring now to FIG. 3B, a cross-sectional illustration of the base substrate 310 after an adhesive 312 is applied is shown, in accordance with an embodiment. In an embodiment, the adhesive 312 is a temporary bond film. For example, the adhesive 312 may be a laser release film. As such, a laser may be provided through the base substrate 310 to release the adhesive 312 at a desired point in the process flow.

Referring now to FIG. 3C, a cross-sectional illustration of the base substrate 310 after glass substrates 305 are attached to the base substrate 310 is shown, in accordance with an embodiment. In an embodiment, the glass substrates 305 have a form factor that is smaller than the form factor of the base substrate 310. For example, the glass substrates 305 may have a quarter panel form factor. In other embodiments, the glass substrates 305 may have a smaller form factor, such as a form factor to accommodate a single electronic package.

Referring now to FIG. 3D, a cross-sectional illustration of the module after a mold layer 301 is disposed over the base substrate 310 and the glass substrates 305 is shown, in accordance with an embodiment. In an embodiment, the mold layer 301 may be an organic material (e.g., dielectric, prepreg, mold materials, epoxy, etc.). In a particular embodiment, the mold layer may be applied with a hot press mold to reduce undulation. The organic material may have fillers to provide a CTE close to the CTE of the glass substrates 305 to reduce warpage and to provide improved mechanical stability (e.g., stiffness).

Referring now to FIG. 3E, a cross-sectional illustration of the module after the mold layer 301 is recessed is shown, in accordance with an embodiment. In an embodiment, the recessing may be done with a planarization or polishing process, such as chemical mechanical planarizing (CMP). The recessing process results in the top surfaces of the glass substrates 305 being exposed.

Referring now to FIG. 3F, a cross-sectional illustration of the carrier 300 after the carrier 300 is released from the base substrate 310 is shown, in accordance with an embodiment. The carrier 300 may be released by exposing a laser to the adhesive 312 through the backside of the base substrate 310. In an embodiment, the released carrier 300 has glass substrates 305 that have top and bottom surfaces that are exposed, similar to the carrier 200 in FIG. 2A.

Referring now to FIG. 3G, a cross-sectional illustration of the carrier 300 after an adhesive 314 is provided over the top surface of the carrier 300 is shown, in accordance with an embodiment. In an embodiment, the adhesive 314 may be a temporary adhesive, such as a laser releasable temporary bond film.

Referring now to FIG. 3H, a cross-sectional illustration of the carrier 300 after package structures 320 are disposed over the glass substrates 305 is shown, in accordance with an embodiment. In an embodiment, an adhesive encapsulant 324 is provided over the adhesive 314. For example, the encapsulant 324 may comprise titanium or the like. A copper layer 325 may be provided over the encapsulant 324. The package structures 320 may comprise a first solder resist 321 over the copper layer 325. Dielectric layers 322 may be provided over the first solder resist 321, and a second solder resist 323 may be provided over the dielectric layers 322. The dielectric layers 322 may include a core in some embodiments. In other embodiments, the dielectric layers 322 may be coreless. Pads, traces, vias, and the like may be provided in the dielectric layers 322 and the solder resist layers 323.

While a particular package structure 320 is shown in FIG. 3H, it is to be appreciated that similar hybrid carriers 300 may be used as a base onto which substantially any package architecture may be built. Additionally, while a single package structure 320 is shown over each of the glass substrates 305, it is to be appreciated that multiple package structures 320 may be provided on a single glass substrate 305.

Referring now to FIG. 3I, a cross-sectional illustration of the module after the glass substrates 305 are released from each other is shown, in accordance with an embodiment. It is to be appreciated that the singulation line 330 does not need to pass through the glass substrates 305. Instead, only the mold layer 301 of the carrier needs to be cut. As such, any glass formulation may be used, including ionized glass formulations.

Referring now to FIG. 3J, a cross-sectional illustration of the modules after first level interconnects (FLIs) to a die 335 are made and the carrier is released is shown, in accordance with an embodiment. In an embodiment, the dies 335 are attached before the carrier is released. After attaching dies 335 the carrier may be released by deactivating the adhesive 314. For example, the adhesive 314 may be released by exposing the adhesive to a laser through the back of the glass substrates 305.

It is to be appreciated that components of the carrier may be reusable. For example, after the base substrate 310 is removed from the carrier 300, the base substrate 310 may be cleaned and reused in a subsequent processing flow. Similarly, the glass substrates 305 may be reused as well. After the release from the package substrates, the remaining mold material 301 may be cleaned from the glass substrates 305, and the glass substrates 305 may be reused.

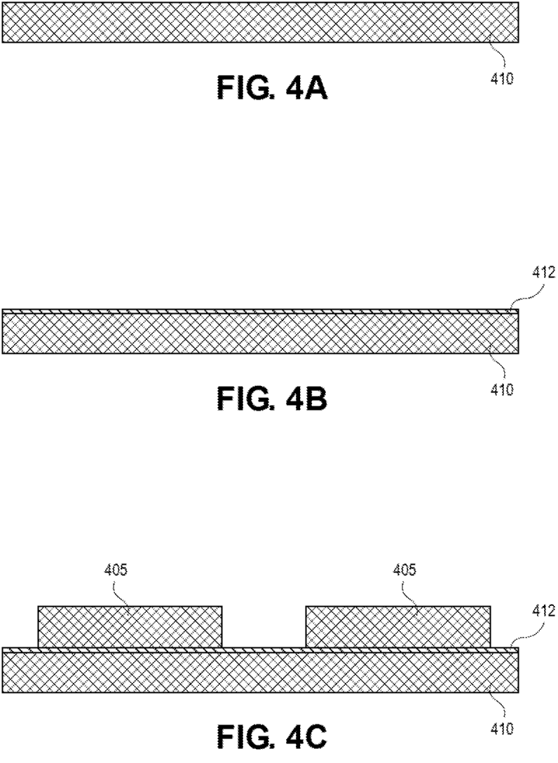

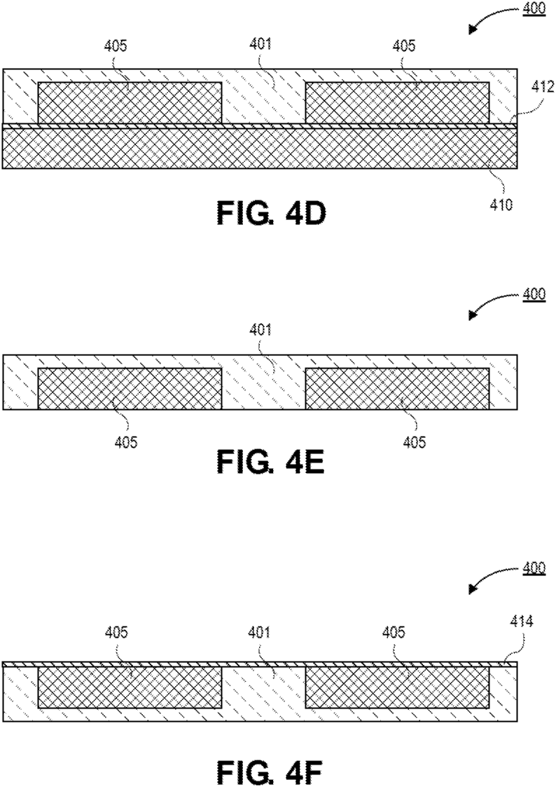

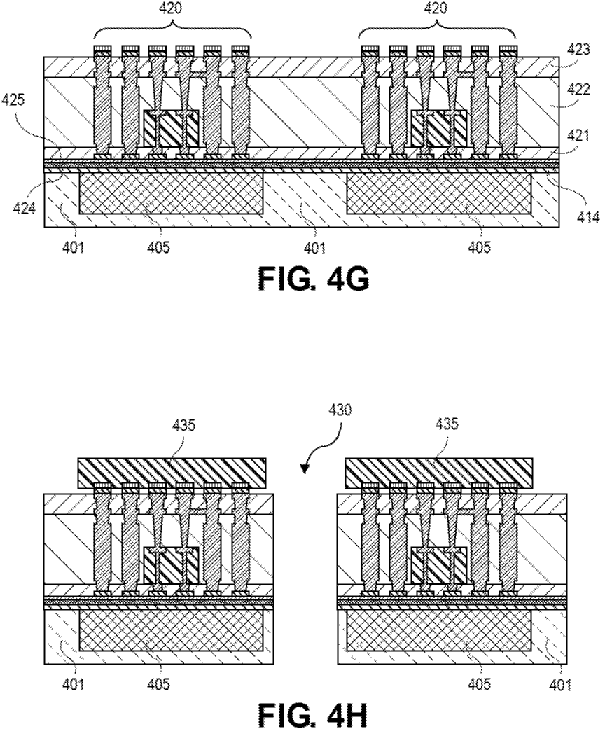

Referring now to FIGS. 4A-4I, a series of cross-sectional illustrations depicting the use of a hybrid carrier to assemble electronic packages is shown, in accordance with an embodiment. The hybrid carrier may be substantially similar to the hybrid carrier 200 shown in FIG. 2B.

Referring now to FIG. 4A, a cross-sectional illustration of a base substrate 410 is shown, in accordance with an embodiment. In an embodiment, the base substrate 410 may be a full panel sized substrate. Though, it is to be appreciated that other form factors may also be used in other embodiments. In an embodiment, the base substrate 410 may comprise a glass substrate.

Referring now to FIG. 4B, a cross-sectional illustration of the base substrate 410 after an adhesive 412 is applied is shown, in accordance with an embodiment. In an embodiment, the adhesive 412 is a temporary bond film. For example, the adhesive 412 may be a laser release film. As such, a laser may be provided through the base substrate 410 to release the adhesive 412 at a desired point in the process flow.

Referring now to FIG. 4C, a cross-sectional illustration of the base substrate 410 after glass substrates 405 are attached to the base substrate 410 is shown, in accordance with an embodiment. In an embodiment, the glass substrates 405 have a form factor that is smaller than the form factor of the base substrate 410. For example, the glass substrates 405 may have a quarter panel form factor. In other embodiments, the glass substrates 405 may have a smaller form factor, such as a form factor to accommodate a single electronic package.

Referring now to FIG. 4D, a cross-sectional illustration of the module after a mold layer 401 is disposed over the base substrate 410 and the glass substrates 405 is shown, in accordance with an embodiment. In an embodiment, the mold layer 401 may be an organic material (e.g., dielectric, prepreg, mold materials, epoxy, etc.). In a particular embodiment, the mold layer may be applied with a hot press mold to reduce undulation. The organic material may have fillers to provide a CTE close to the CTE of the glass substrates 405 to reduce warpage and to provide improved mechanical stability (e.g., stiffness). In contrast to the embodiment described with respect to FIGS. 3A-3J, the mold layer 401 persists over the surface of the glass substrates 405. That is, only a single surface of the glass substrates 405 is exposed after the base substrate 410 is removed.

Referring now to FIG. 4E, a cross-sectional illustration of the carrier 400 after the carrier 400 is released from the base substrate 410 is shown, in accordance with an embodiment. The carrier 400 may be released by exposing a laser to the adhesive 412 through the backside of the base substrate 410. In an embodiment, the released carrier 400 has glass substrates 405 that have a single surface exposed, similar to the carrier 200 in FIG. 2B.

Referring now to FIG. 4F, a cross-sectional illustration of the carrier 400 after an adhesive 414 is provided over the top surface of the carrier 400 is shown, in accordance with an embodiment. In an embodiment, the adhesive 414 may be a temporary adhesive, such as a laser releasable temporary bond film.

Referring now to FIG. 4G, a cross-sectional illustration of the carrier 400 after package structures 420 are disposed over the glass substrates 405 is shown, in accordance with an embodiment. In an embodiment, an adhesive encapsulant 424 is provided over the adhesive 414. For example, the encapsulant 424 may comprise titanium or the like. A copper layer 425 may be provided over the encapsulant 424. The package structures 420 may comprise a first solder resist 421 over the copper layer 425. Dielectric layers 422 may be provided over the first solder resist 421, and a second solder resist 423 may be provided over the dielectric layers 422. The dielectric layers 422 may include a core in some embodiments. In other embodiments, the dielectric layers 422 may be coreless. Pads, traces, vias, and the like may be provided in the dielectric layers 422 and the solder resist layers 423.

While a particular package structure 420 is shown in FIG. 4G, it is to be appreciated that similar hybrid carriers 400 may be used as a base onto which substantially any package architecture may be built. Additionally, while a single package structure 420 is shown over each of the glass substrates 405, it is to be appreciated that multiple package structures 420 may be provided on a single glass substrate 405.

Referring now to FIG. 4H, a cross-sectional illustration of the module after the glass substrates 405 are released from each other is shown, in accordance with an embodiment. It is to be appreciated that the singulation line 430 does not need to pass through the glass substrates 405. Instead, only the mold layer 401 of the carrier needs to be cut. As such, any glass formulation may be used, including ionized glass formulations. In an embodiment, FLIs to a die 435 may be made as well. The dies 435 may be attached before the singulation or after the singulation.

Referring now to FIG. 4I, a cross-sectional illustration of the modules after the carrier is released is shown, in accordance with an embodiment. In an embodiment, the carrier may be released by deactivating the adhesive 414. For example, the adhesive 414 may be released by exposing the adhesive to a laser through the back of the glass substrates 405. In some embodiments, the mold layer 401 over the backside surface of the glass substrates 405 may be recessed in order to allow for the laser to pass through the glass substrates 405.

It is to be appreciated that components of the carrier may be reusable. For example, after the base substrate 410 is removed from the carrier 400, the base substrate 410 may be cleaned and reused in a subsequent processing flow. Similarly, the glass substrates 405 may be reused as well. After the release from the package substrates, the remaining mold material 401 may be cleaned from the glass substrates 405, and the glass substrates 405 may be reused.

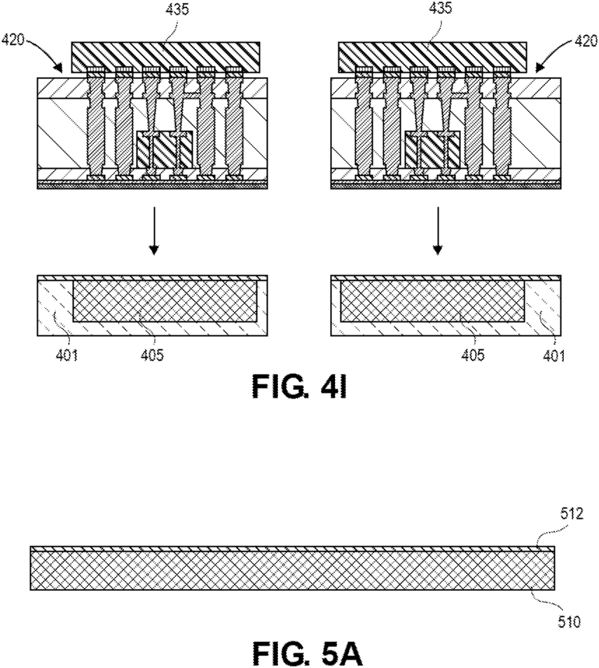

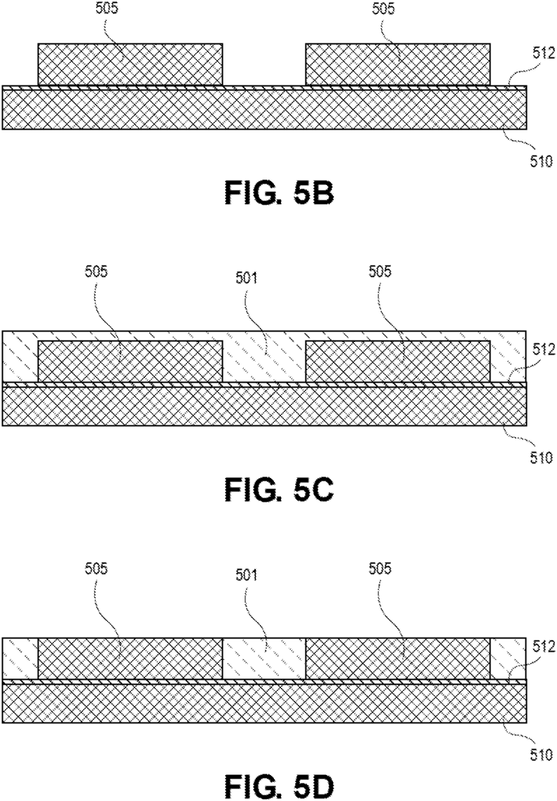

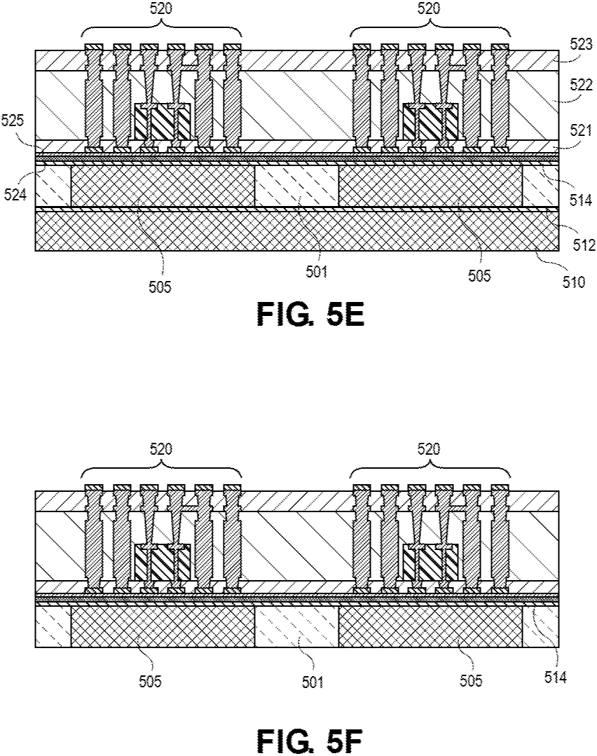

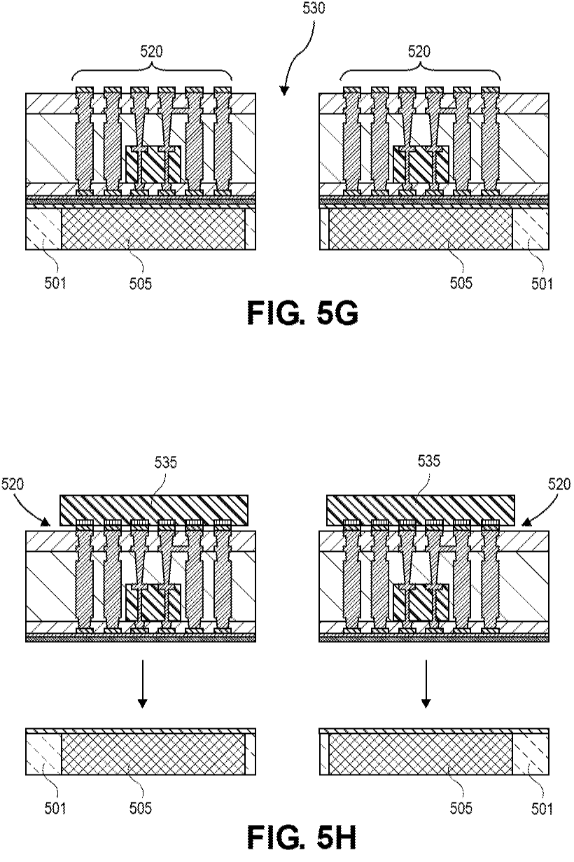

Referring now to FIGS. 5A-5H, a series of cross-sectional illustrations depicting the use of a hybrid carrier to assemble electronic packages is shown, in accordance with an embodiment. The hybrid carrier may be substantially similar to the hybrid carrier 200 shown in FIG. 2C.

Referring now to FIG. 5A, a cross-sectional illustration of a base substrate 510 is shown, in accordance with an embodiment. In an embodiment, the base substrate 510 may be a full panel sized substrate. Though, it is to be appreciated that other form factors may also be used in other embodiments. In an embodiment, the base substrate 510 may comprise a glass substrate. In an embodiment, an adhesive 512 may be applied to the base substrate 510. In an embodiment, the adhesive 512 is a temporary bond film. For example, the adhesive 512 may be a laser release film. As such, a laser may be provided through the base substrate 510 to release the adhesive 512 at a desired point in the process flow.

Referring now to FIG. 5B, a cross-sectional illustration of the base substrate 510 after glass substrates 505 are attached to the base substrate 510 is shown, in accordance with an embodiment. In an embodiment, the glass substrates 505 have a form factor that is smaller than the form factor of the base substrate 510. For example, the glass substrates 505 may have a quarter panel form factor. In other embodiments, the glass substrates 505 may have a smaller form factor, such as a form factor to accommodate a single electronic package.

In an embodiment, a thickness of the glass substrates 505 may be different than a thickness of the base substrate 510. For example, the base substrate 510 may be thicker than the glass substrates 505. Additionally, the quality of the glass may be different between the glass substrates 505 and the base substrate 510. For example, the glass substrates 505 may be a higher quality glass than the base substrate 510.

Referring now to FIG. 5C, a cross-sectional illustration of the module after a mold layer 501 is disposed over the base substrate 510 and the glass substrates 505 is shown, in accordance with an embodiment. In an embodiment, the mold layer 501 may be an organic material (e.g., dielectric, prepreg, mold materials, epoxy, etc.). In a particular embodiment, the mold layer may be applied with a hot press mold to reduce undulation. The organic material may have fillers to provide a CTE close to the CTE of the glass substrates 505 to reduce warpage and to provide improved mechanical stability (e.g., stiffness).

Referring now to FIG. 5D, a cross-sectional illustration of the module after the mold layer 501 is recessed is shown, in accordance with an embodiment. In an embodiment, the recessing may be done with a planarization or polishing process, such as CMP. The recessing process results in the top surfaces of the glass substrates 505 being exposed.

Referring now to FIG. 5E, a cross-sectional illustration of the carrier after package structures 520 are disposed over the glass substrates 505 is shown, in accordance with an embodiment. In an embodiment, an adhesive encapsulant 524 is provided over the adhesive 514. For example, the encapsulant 524 may comprise titanium or the like. A copper layer 525 may be provided over the encapsulant 524. The package structures 520 may comprise a first solder resist 521 over the copper layer 525. Dielectric layers 522 may be provided over the first solder resist 521, and a second solder resist 523 may be provided over the dielectric layers 522. The dielectric layers 522 may include a core in some embodiments. In other embodiments, the dielectric layers 522 may be coreless. Pads, traces, vias, and the like may be provided in the dielectric layers 522 and the solder resist layers 523.

While a particular package structure 520 is shown in FIG. 5E, it is to be appreciated that similar hybrid carriers may be used as a base onto which substantially any package architecture may be built. Additionally, while a single package structure 520 is shown over each of the glass substrates 505, it is to be appreciated that multiple package structures 520 may be provided on a single glass substrate 505.

Referring now to FIG. 5F, a cross-sectional illustration of the module after the base substrate 510 is removed is shown, in accordance with an embodiment. In an embodiment, the base substrate 510 may be removed by deactivating the adhesive layer 512. For example, a laser may pass through the backside of the base substrate 510 to deactivate the adhesive 512.

Referring now to FIG. 5G, a cross-sectional illustration of the module after the glass substrates 505 are released from each other is shown, in accordance with an embodiment. It is to be appreciated that the singulation line 530 does not need to pass through the glass substrates 505. Instead, only the mold layer 501 of the carrier needs to be cut. As such, any glass formulation may be used, including ionized glass formulations.

Referring now to FIG. 5H, a cross-sectional illustration of the modules after FLIs to a die 535 are made and the carrier is released is shown, in accordance with an embodiment. In an embodiment, the dies 535 are attached before the carrier is released. After attaching dies 535 the carrier may be released by deactivating the adhesive 514. For example, the adhesive 514 may be released by exposing the adhesive to a laser through the back of the glass substrates 505.

It is to be appreciated that components of the carrier may be reusable. For example, after the base substrate 510 is removed from the carrier 500, the base substrate 510 may be cleaned and reused in a subsequent processing flow. Similarly, the glass substrates 505 may be reused as well. After the release from the package substrates, the remaining mold material 501 may be cleaned from the glass substrates 505, and the glass substrates 505 may be reused.

In the embodiments described above, it is to be appreciated that releasing the package structure from the underlying hybrid carrier is implemented with a laser exposure of the adhesive. However, the laser can typically only pass through the glass substrates. That is, the adhesive at the interface between the mold layer and the package structure may not be deactivated by the laser exposure. This can lead to portions of the package structure being stuck to the hybrid carrier, and make the release from the hybrid carrier more difficult.

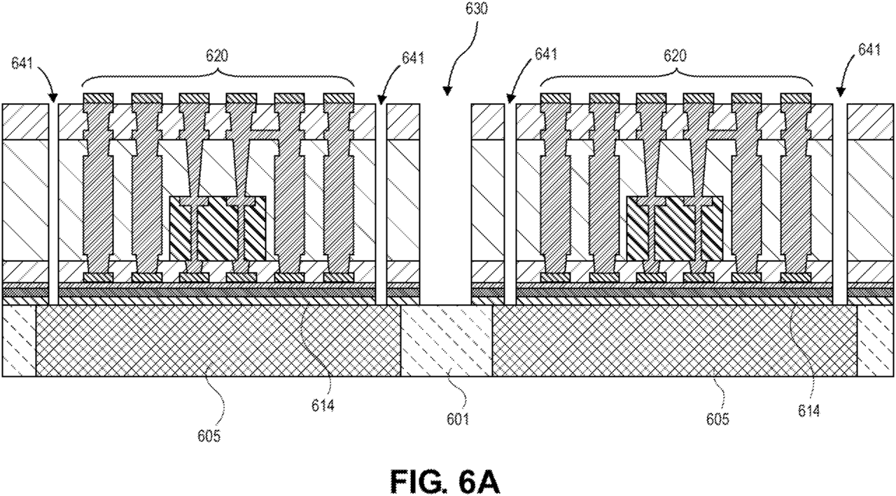

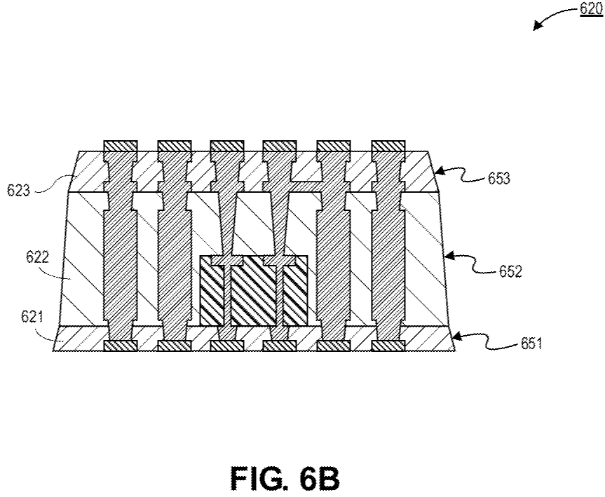

Accordingly, embodiments disclosed herein may also include the use of a release trench. The release trench is within a footprint of the glass substrate. As such, the entire portion of the package structure within the perimeter of the release trench is able to be fully released. An example of such an embodiment is shown in FIG. 6A.

Referring now to FIG. 6A, a cross-sectional illustration of a module with package structures 620 over a hybrid carrier is shown, in accordance with an embodiment. The hybrid carrier may comprise glass substrates 605 that are embedded within a mold layer 601. In an embodiment, a singulation trench 630 may be provided between the package structures 620. The singulation trench 630 may be positioned over the mold layer 601.

In an embodiment, a release trench 641 is provided through the package structure around the conductive features (e.g., pads, vias, traces, etc.) of the package structures 620. The release trench 641 is entirely within a footprint of the underlying glass substrate 605. As such, the adhesive 614 between the package structure 620 and the glass substrate 605 can be entirely deactivated by a laser. That is, there is no portion of the package structure 620 that is over the mold layer 601. The portions over the mold layer may remain adhered to the hybrid carrier, and the package structures 620 can be separated from the hybrid carrier after the adhesive 614 is deactivated.

In an embodiment, the release trenches 641 may be formed with any drilling process. For example, a mechanical drilling process may be used. In other embodiments, a laser drilling process may be used. In the case of a laser drilling process, embodiments may include package structures with sidewalls that are tapered. An example of such an embodiment is shown in FIG. 6B.

Referring now to FIG. 6B, a cross-sectional illustration of a package structure 620 is shown, in accordance with an embodiment. As shown, the package structure 620 comprises a first solder resist layer 621, dielectric layers 622, and a second solder resist layer 623. The sidewalls 651-653 of the package structure 620 may be sloped. The slope is characteristic of the laser drilling process. Additionally, it is to be appreciated that the slopes of the different portions of the sidewalls 651-653 may be non-uniform. For example, the slope of the sidewall 652 through the dielectric layers 622 is different than the slopes of the sidewalls 651 and 653 through the solder resist layers 621 and 623. Additionally, it is to be appreciated that there may be an absence of undercuts between each of the layers, as would typically be the case if an etching process were used to form the release trenches 641.

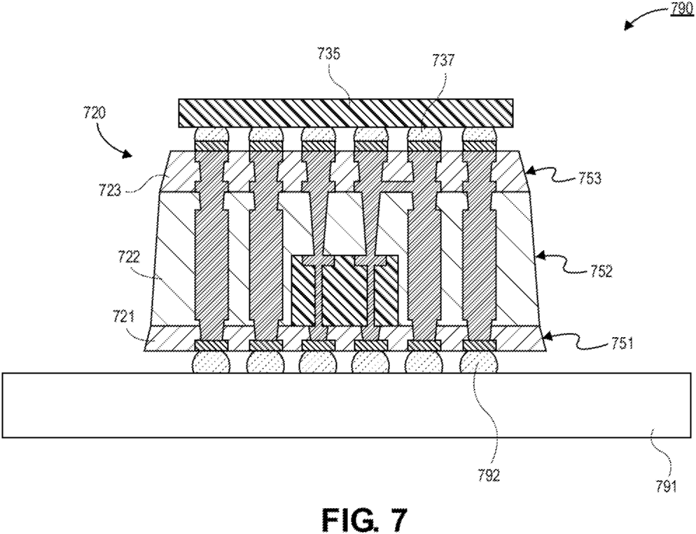

Referring now to FIG. 7, a cross-sectional illustration of an electronic system 790 is shown, in accordance with an embodiment. In an embodiment, the electronic system 790 comprises a board 791, such as a printed circuit board (PCB) or the like. The board 791 is coupled to a package structure 720 by interconnects 792. The interconnects 792 may be solder balls, sockets, or other suitable interconnect architecture.

In an embodiment, the package structure 720 may comprise a first solder resist 721, dielectric layers 722, and a second solder resist 723. Sidewalls 751-753 may be sloped. For example, the sidewalls 751-753 may be sloped due to a laser drilling process used to release the package structure 720 from a carrier (not shown). In an embodiment, FLIs 737 may couple the package structure 720 to a die 735.

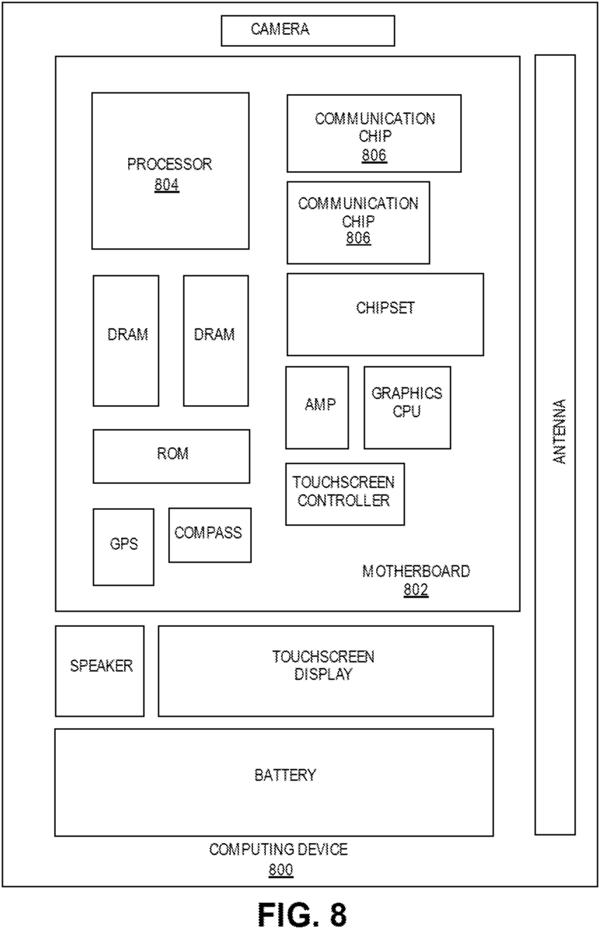

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package that comprises sidewalls that are sloped as a result of a laser drilling process, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package that comprises sidewalls that are sloped as a result of a laser drilling process, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a carrier for electronic packaging assembly, comprising: a mold layer with a first surface and a second surface; and a plurality of glass substrates embedded in the mold layer, wherein individual ones of the glass substrates comprise a third surface and a fourth surface, wherein the third surface of the glass substrate is substantially coplanar with the first surface of the mold layer.

Example 2: the carrier of Example 1, wherein the mold layer is panel sized, and wherein the individual ones of the plurality of glass substrates are quarter panel sized.

Example 3: the carrier of Example 1 or Example 2, wherein individual ones of the plurality of glass substrates are sized to fit a single electronic package.

Example 4: the carrier of Examples 1-3, wherein the fourth surface of the glass substrate is substantially coplanar with the second surface of the mold layer.

Example 5: the carrier of Examples 1-3, wherein the mold layer covers the fourth surface of the glass substrate.

Example 6: the carrier of Examples 1-3, further comprising: a glass base over the second surface of the mold layer.

Example 7: the carrier of Example 6, wherein the fourth surface of the glass substrates is adhered to the glass base.

Example 8: the carrier of Example 6 or Example 7, wherein a thickness of the glass base is greater than a thickness of the glass substrates.

Example 9: the carrier of Examples 6-9, wherein the glass base is adhered to the glass substrates by a temporary adhesive layer.

Example 10: the carrier of Examples 1-9, wherein the mold layer forms an outer frame that surrounds a perimeter of the plurality of glass substrates.

Example 11: a method of assembling an electronic package, comprising: applying a first adhesive over a glass carrier; attaching a plurality of glass substrates to the glass carrier with the first adhesive; disposing a mold layer over and around the plurality of glass substrates; releasing the glass carrier; applying a second adhesive over the plurality of glass substrates and the mold layer; forming a package substrate stack over individual ones of the plurality of glass substrates; and singulating the plurality of glass substrates.

Example 12: the method of Example 11, further comprising: attaching dies to the package substrate stacks.

Example 13: the method of Example 12, further comprising: releasing the plurality of glass substrates from the package substrate stacks.

Example 14: the method of Examples 11-13, wherein the glass carrier is a panel sized carrier.

Example 15: the method of Example 14, wherein the glass substrates are quarter panel sized substrates.

Example 16: the method of Examples 11-15, wherein a single one of the package substrate stacks are provided over individual ones of the glass substrates.

Example 17: the method of Examples 11-16, further comprising: recessing the mold layer to expose a surface of the glass substrates.

Example 18: the method of Examples 11-17, further comprising: forming a trench around perimeters of the package substrate stacks, wherein the trenches land on the glass substrate below each package substrate stack.

Example 19: a package substrate, comprising: a plurality of dielectric layers; vias through the dielectric layers; a first layer over the plurality of dielectric layers; and a second layer under the plurality of dielectric layers, wherein a profile of an edge of the package substrate comprises non-vertical sidewalls.

Example 20: the package substrate of Example 19, wherein the slope of the non-vertical sidewalls is non-uniform through a thickness of the package substrate.

Example 21: the package substrate of Example 20, wherein a sidewall of the first layer has a first slope, and wherein a sidewall of the plurality of dielectric layers has a second slope that is different than the first slope.

Example 22: the package substrate of Example 21, wherein a sidewall of the second layer has the first slope.

Example 23: the package substrate of Examples 19-22, wherein the profile of the edge of the package substrate comprises substantially no undercuts at junctions between layers of the package substrate.

Example 24: an electronic system, comprising: a board; a package substrate coupled to the board, wherein the package substrate comprises: a plurality of dielectric layers; vias through the dielectric layers; a first layer over the plurality of dielectric layers; and a second layer under the plurality of dielectric layers, wherein a profile of an edge of the package substrate comprises non-vertical sidewalls; and a die coupled to the package substrate.

Example 25: the electronic system of Example 24, wherein the slope of the non-vertical sidewalls is non-uniform through a thickness of the package substrate.

What is claimed is:

1. A carrier for electronic packaging assembly, comprising:
a mold layer with a first surface and a second surface; and
a plurality of glass substrates embedded in the mold layer, wherein individual ones of the glass substrates comprise a third surface and a fourth surface, wherein the third surface of the glass substrate is substantially coplanar with the first surface of the mold layer.

2. The carrier of claim 1, wherein the mold layer is panel sized, and wherein the individual ones of the plurality of glass substrates are quarter panel sized.

3. The carrier of claim 1, wherein individual ones of the plurality of glass substrates are sized to fit a single electronic package.

4. The carrier of claim 1, wherein the fourth surface of the glass substrate is substantially coplanar with the second surface of the mold layer.

5. The carrier of claim 1, wherein the mold layer covers the fourth surface of the glass substrate.

6. The carrier of claim 1, further comprising:
a glass base over the second surface of the mold layer.

7. The carrier of claim 6, wherein the fourth surface of the glass substrates is adhered to the glass base.

8. The carrier of claim 6, wherein a thickness of the glass base is greater than a thickness of the glass substrates.

9. The carrier of claim 6, wherein the glass base is adhered to the glass substrates by a temporary adhesive layer.

10. The carrier of claim 1, wherein the mold layer forms an outer frame that surrounds a perimeter of the plurality of glass substrates.

11. A method of assembling an electronic package, comprising:
applying a first adhesive over a glass carrier;
attaching a plurality of glass substrates to the glass carrier with the first adhesive;
disposing a mold layer over and around the plurality of glass substrates;
releasing the glass carrier;
applying a second adhesive over the plurality of glass substrates and the mold layer;
forming a package substrate stack over individual ones of the plurality of glass substrates; and
singulating the plurality of glass substrates.

12. The method of claim 11, further comprising:
attaching dies to the package substrate stacks.

13. The method of claim 12, further comprising:
releasing the plurality of glass substrates from the package substrate stacks.

14. The method of claim 11, wherein the glass carrier is a panel sized carrier.

15. The method of claim 14, wherein the glass substrates are quarter panel sized substrates.

16. The method of claim 11, wherein a single one of the package substrate stacks are provided over individual ones of the glass substrates.

17. The method of claim 11, further comprising:
recessing the mold layer to expose a surface of the glass substrates.

18. The method of claim 11, further comprising:
forming a trench around perimeters of the package substrate stacks, wherein the trenches land on the glass substrate below each package substrate stack.

19. A package substrate, comprising:
a plurality of dielectric layers;
vias through the dielectric layers;
a first layer over the plurality of dielectric layers; and
a second layer under the plurality of dielectric layers, wherein a profile of an edge of the package substrate comprises non-vertical sidewalls.

20. The package substrate of claim 19, wherein the slope of the non-vertical sidewalls is non-uniform through a thickness of the package substrate.

21. The package substrate of claim 20, wherein a sidewall of the first layer has a first slope, and wherein a sidewall of the plurality of dielectric layers has a second slope that is different than the first slope.

22. The package substrate of claim 21, wherein a sidewall of the second layer has the first slope.

23. The package substrate of claim 19, wherein the profile of the edge of the package substrate comprises substantially no undercuts at junctions between layers of the package substrate.

24. An electronic system, comprising:
a board;
a package substrate coupled to the board, wherein the package substrate comprises:
a plurality of dielectric layers;
vias through the dielectric layers;
a first layer over the plurality of dielectric layers; and
a second layer under the plurality of dielectric layers, wherein a profile of an edge of the package substrate comprises non-vertical sidewalls; and
a die coupled to the package substrate.

25. The electronic system of claim 24, wherein the slope of the non-vertical sidewalls is non-uniform through a thickness of the package substrate.
